(19) United States
(12) Patent Application Publication
(10) Pub. No.: US 2025/0024941 A1
(43) Pub. Date: Jan. 23, 2025

(54) SUBSTRATE LOADING APPARATUS

(71) Applicant: Samsung Display Co., Ltd., Yongin-Si (KR)

(72) Inventors: MINCHUL JUNG, Yongin-si (KR); HYUN-HOO SEO, Yongin-si (KR)

(21) Appl. No.: 18/738,525

(22) Filed: Jun. 10, 2024

(30) Foreign Application Priority Data
Jul. 20, 2023 (KR) 10-2023-0094674

(51) Int. Cl. A47B 81/00; A47B 47/02

(52) U.S. Cl. CPC A47B 81/00; A47B 47/022; A47B 47/027

(57) ABSTRACT

Provided is a substrate loading apparatus including a first frame and a second frame, a support frame and including a front surface adjacent to a substrate and a rear surface facing the front surface, and a support bar coupled to the support frame, extending in a second direction, and supporting the substrate. The support bar includes an extension member and a coupling member configured to couple the extension member and the support frame to each other. The coupling member includes a first surface which protrudes toward the support frame and is a curved surface having a first curvature. The support frame includes a second surface which faces the first surface and is a curved surface having the first curvature of the first surface. The first surface and the second surface may be in surface contact with each other.

### CROSS-REFERENCE TO RELATED APPLICATIONS

This U.S. non-provisional patent application claims priority under 35 U.S.C. § 119 of Korean Patent Application No. 10-2023-0094674, filed on Jul. 20, 2023, the entire contents of which are hereby incorporated by reference.

### BACKGROUND

The present disclosure herein relates to a substrate loading apparatus, and more particularly, to a substrate loading apparatus having a frame including a curved surface.

Generally, display devices include a display panel in which a plurality of elements are disposed. When a display panel is manufactured, a metal thin film, an inorganic layer, and the like for forming these elements are formed on a substrate.

A substrate processing system is used to form a metal thin film, an inorganic layer, and the like on the substrate of the display panel. The substrate processing system includes a cassette configured to accommodate the substrate, a transfer apparatus configured to transfer the substrate from the cassette, and a substrate processing apparatus configured to receive the substrate from the transfer apparatus and perform a substrate processing process to form the metal thin film and the inorganic layer.

A cleaning process is performed to remove contaminants formed on the surface of the substrate in a previous process before proceeding with a next process. The cleaning process is carried out by coupling the substrate to a fixing part of a substrate loading unit.

### SUMMARY

The present disclosure provides a substrate loading apparatus that prevents a support bar supporting a substrate from sagging and allows the support bar to be adjusted.

An embodiment of the inventive concept provides a substrate loading apparatus including a first frame and a second frame facing each other, a support frame disposed between the first frame and the second frame, extending along a first direction, and including a front surface adjacent to a substrate and a rear surface facing the front surface, and a support bar coupled to the support frame, extending in a second direction crossing the first direction, and supporting the substrate. The support bar includes an extension member extending in the second direction and a coupling member configured to couple the extension member and the support frame to each other. The coupling member includes a first surface which protrudes toward the support frame and is a curved surface having a first curvature. The support frame includes a second surface which faces the first surface and is a curved surface having the first curvature of the first surface. The first surface and the second surface may be in surface contact with each other.

In an embodiment, the first surface and the second surface may be spherical surfaces.

In an embodiment, the support frame may have a first through hole which is defined therein, overlaps the second surface, extends along the second direction, and passes through the support frame. The coupling member may have a second through hole which is defined therein, overlaps the first surface, extends along the second direction, and passes through the coupling member.

In an embodiment of the inventive concept, the substrate loading apparatus may further include a bolt passing through the first and second through holes and a nut screwed to the bolt. The coupling member and the support frame may be coupled to each other by the bolt and the nut.

In an embodiment, the nut may include a third surface which is in contact with the coupling member and is a curved surface having a second curvature. The coupling member may include a fourth surface which is in surface contact with the third surface and is a curved surface having the second curvature of the third surface.

In an embodiment, a head portion of the bolt may be in surface contact with the support frame.

In an embodiment, the first curvature and the second curvature may be the same as each other.

In an embodiment, the third surface and the fourth surface may be spherical surfaces.

In an embodiment, the bolt may be spaced apart by a predetermined distance from an inner side surface of the support frame defining the first through hole and an inner side surface of the coupling member defining the second through hole.

In an embodiment, the second through hole may be provided in plurality and the plurality of second through holes may include (2-1)-th and (2-2)-th through holes disposed along the first direction with the extension member interposed therebetween. The first through hole may be provided in plurality and the plurality of first through holes may include (1-1)-th and (1-2)-th through holes disposed at positions respectively corresponding to the (2-1)-th and (2-2)-th through holes.

In an embodiment, the second through hole may be provided in plurality and the plurality of second through holes may include (2-3)-th and (2-4)-th through holes disposed along a third direction crossing the first direction and the second direction with the extension member interposed therebetween. The first through hole may be provided in plurality and the plurality of first through holes may include (1-3)-th and (1-4)-th through holes disposed at positions respectively corresponding to the (2-3)-th and (2-4)-th through holes.

In an embodiment, the second surface may be a portion of the front surface.

In an embodiment, a third through hole through which the extension member passes may be defined in the support frame, and the second surface may be a portion of the rear surface.

In an embodiment, the first surface may be able to move along the second surface.

In an embodiment of the inventive concept, a substrate loading apparatus includes a support frame extending along a first direction and including a front surface adjacent to a substrate and a rear surface facing the front surface, and a support bar coupled to the support frame, extending in a second direction crossing the first direction, and supporting the substrate. The support bar includes an extension member extending in the second direction and a coupling member coupling the extension member and the support frame to each other. The coupling member may include a protruding surface that is a spherical surface protruding toward the support frame. A seating groove in which the protruding surface is seated may be defined in the support frame. The protruding surface and one surface of the support frame defining the seating groove may be in surface contact with each other.

In an embodiment, a first through hole, which overlaps the seating groove, extends along the second direction, and passes through the support frame, may be defined in the support frame. A second through hole, which overlaps the protruding surface, extends along the second direction, and passes through the coupling member, may be defined in the coupling member.

In an embodiment, the substrate loading apparatus may further include a bolt which passes through the first and second through holes and a nut screwed to the bolt. One surface of the nut may be a first curved surface, and a contact surface of the coupling member in contact with the one surface may be a second curved surface corresponding to the first curved surface.

In an embodiment, a head portion of the bolt may be in surface contact with the support frame.

In an embodiment, the first through hole may be provided in plurality and the plurality of first through holes may include (1-3)-th and (1-4)-th through holes disposed along a third direction crossing the first direction and the second direction with the extension member interposed therebetween. The second through hole may be provided in plurality and the plurality of second through holes may include (2-3)-th and (2-4)-th through holes disposed at positions respectively corresponding to the (1-3)-th and (1-4)-th through holes.

In an embodiment, a third through hole through which the extension member passes may be defined in the support frame, and the seating groove may be defined on the rear surface.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

FIG. 1 is a perspective view of a substrate loading apparatus according to an embodiment of the inventive concept.

FIG. 2 is a front view of the substrate loading apparatus according to an embodiment of the inventive concept.

FIG. 3 is a side view of the substrate loading apparatus according to an embodiment of the inventive concept.

FIG. 4 is a perspective view of a support bar and a support frame according to an embodiment of the inventive concept.

FIG. 5 is a cross-sectional view before coupling the support bar and the support frame to each other according to an embodiment of the inventive concept.

FIG. 6 is a cross-sectional view after coupling the support bar and the support frame to each other according to an embodiment of the inventive concept.

FIGS. 7A and 7B are cross-sectional views illustrating a difference in an extension direction of the support bar according to an embodiment of the inventive concept.

FIG. 8 is a cross-sectional view after coupling a support bar and a support frame to each other according to an embodiment of the inventive concept.

FIG. 9 is a perspective view of a support bar and a support frame according to an embodiment of the inventive concept.

### DETAILED DESCRIPTION

In this specification, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the inventive concept. Similarly, the second element may also be referred to as the first element. The terms of a singular form include a plural form unless otherwise specified.

Terms, such as “below”, “lower”, “above”, “upper” and the like, are used herein for ease of description to describe one element's relationship to another element(s) as illustrated in the drawings. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

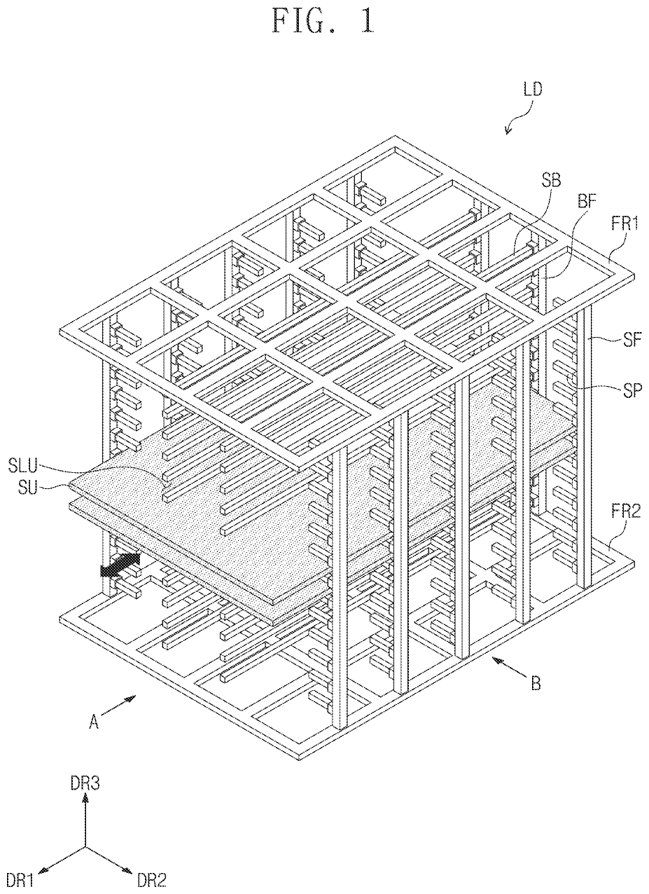

FIG. 1 is a perspective view of a substrate loading apparatus LD according to an embodiment of the inventive concept.

Referring to FIG. 1, the substrate loading apparatus LD is a device that simultaneously loads a plurality of substrates SU. A plurality of slots SLU may be formed in the substrate loading apparatus LD, and a substrate SU may be accommodated in each of the slots SLU. The plurality of substrates SU may be arranged in a third direction DR3. The plurality of substrates SU may be parallel to a plane defined by a first direction DR1 and a second direction DR2. The plurality of substrates SU may be disposed to be parallel to the plane defined by the first direction DR1 and the second direction DR2.

Here, the first direction DR1 and the second direction DR2 are orthogonal to each other, and the third direction DR3 may be a direction normal to the plane defined by the first direction DR1 and the second direction DR2. The first to third directions DR1, DR2, and DR3 described in this specification are relative concepts and may be converted into other directions.

The substrates SU may be elements which are used in a display device. For example, the substrates SU may be ultra-thin-glass (UTG) substrates having a relatively small thickness. The thickness of each of the substrates SU which are loaded on the substrate loading apparatus LD according to an embodiment of the inventive concept may be about 100 μm or less.

The substrate loading apparatus LD may include a first frame FR1, a second frame FR2, a side frame SF, a support frame BF, a side slot bar SP, and a support bar SB. The first frame FR1 and the second frame FR2 may face each other in the third direction DR3. The first frame FR1 may form the upper side of the substrate loading apparatus LD, and the second frame FR2 may form the lower side of the substrate loading apparatus LD. The first frame FR1 and the second frame FR2 may be parallel to a plane defined by the first direction DR1 and the second direction DR2. The first frame FR1 and the second frame FR2 may be spaced apart from each other along the third direction DR3 and face each other.

The first frame FR1 and the second frame FR2 may contain a heat-resistant material that is not deformed at a high temperature. For example, the first frame FR1 and the second frame FR2 may contain a metal material or a carbon composite that is not deformed even at a temperature of about 400 degrees, and the inventive concept is not limited to any one embodiment.

The side frame SF may be disposed between the first frame FR1 and the second frame FR2 and extend along the third direction DR3. The side frame SF may constitute the left and right sides of the substrate loading apparatus LD and connect the first frame FR1 and the second frame FR2 to each other. The side frame SF may be provided in a plurality, and the plurality of side frames SF may be arranged along the first direction DR1. The plurality of side frames SF may be disposed to be spaced apart from each other at regular intervals. The side frame SF may contain a heat-resistant material that is not deformed at a high temperature.

The side slot bar SP may be coupled to the inner side surface of the side frame SF to support the substrates SU accommodated inside the substrate loading apparatus LD. The side slot bar SP may be provided in plurality, and the side slot bars SP may be disposed to be spaced apart from each other at equal intervals along the third direction DR3 (the extension direction) of the side frame SF. The minimum distance between two side slot bars SP that are most adjacent to each other among the plurality of side slot bars SP may be greater than the thickness of the substrate SU. The side slot bar SP may contain a heat-resistant material that is not deformed at a high temperature.

The support frame BF (or rear frame) may be disposed between the first frame FR1 and the second frame FR2 and extend along the third direction DR3. The support frame BF may constitute the rear side of the substrate loading apparatus LD and connect the first frame FR1 and the second frame FR2 to each other. As the support frame BF is not disposed in the front side of the substrate loading apparatus LD, the substrates SU may be able to enter and exit from the front of the substrate loading apparatus LD. The support frame BF may be provided in plurality, and the plurality of support frames BF may be arranged along the second direction DR2. The support frames BF may be disposed to be spaced apart from each other at regular intervals. The support frame BF may contain a heat-resistant material that is not deformed at a high temperature.

The support bar SB may be coupled to the support frame BF and extend in the first direction DR1. One end of the support bar SB may be coupled to the support frame BF, and the other end of the support bar SB may be a free end. The support bar SB may support the substrates SU loaded inside the substrate loading apparatus LD. The support bar SB may be provided in plurality, and the plurality of support bars SB may be arranged along the third direction DR3. The plurality of support bars SB may be disposed to be spaced apart from each other at equal intervals along the third direction DR3. The minimum distance between two support bars SB that are most adjacent to each other among the plurality of support bars SB may be greater than the thickness of the substrate SU. The support bar SB may contain a heat-resistant material that is not deformed at a high temperature.

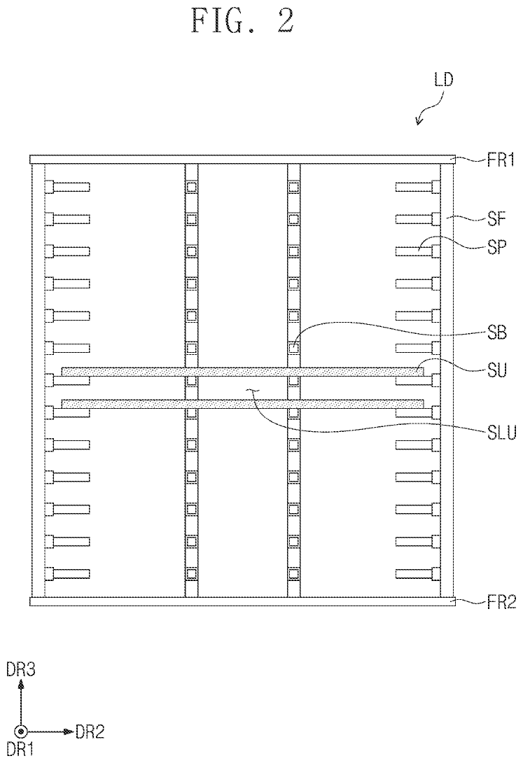

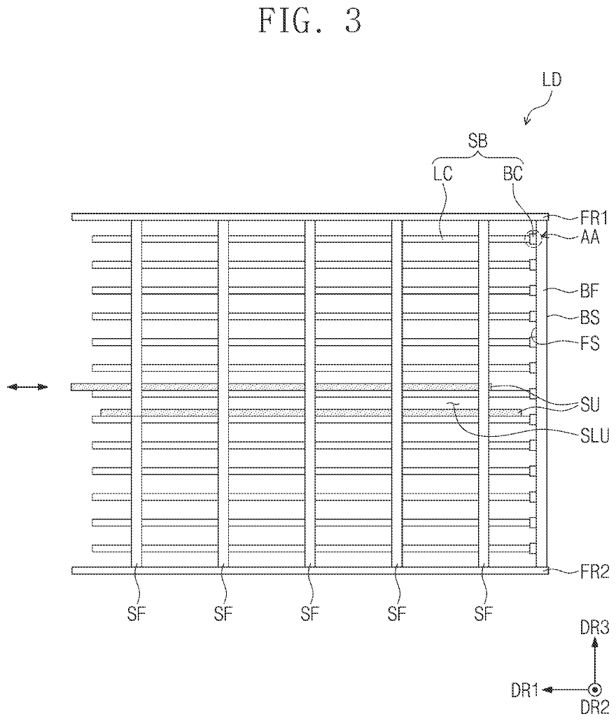

FIG. 2 is a front view of the substrate loading apparatus according to an embodiment of the inventive concept. FIG. 3 is a side view of the substrate loading apparatus according to an embodiment of the inventive concept. More specifically, FIG. 2 is a front view of the substrate loading apparatus of FIG. 1 viewed from a direction A, and FIG. 3 is a side view of the substrate loading apparatus of FIG. 1 viewed from a direction B.

Referring to FIGS. 2 and 3, the first frame FR1 and the second frame FR2 may respectively form the upper and lower sides of the substrate loading apparatus LD. The support frame BF may constitute the rear side of the substrate loading apparatus LD, and the side frame SF may constitute the side of the substrate loading apparatus LD. Since the front side of the substrate loading apparatus LD is open, it is possible for the substrates SU to enter and exit therefrom.

The support bars SB together with the side slot bars SP may form a plurality of slots SLU in which the substrates SU are accommodated. The plurality of slots SLU may be formed between adjacent support bars SB in the third direction DR3. The plurality of slots SLU may be formed between adjacent side slot bars SP in the third direction DR3. One substrate SU may be loaded in each of the plurality of slots SLU. The support bars SB and the side slot bars SP may support the lower surface of the substrate SU loaded in the slot SLU.

The support bars SB disposed adjacent to the central portion of each of the substrates SU in the second direction DR2 may prevent the central portions of the substrates SU from sagging. The side slot bars SP disposed adjacent to the side portion of each of the substrates SU in the second direction DR2 may prevent the side portions of the substrates SU from sagging. FIG. 2 illustrates that two support bars SB support the center of a substrate SU, but the arrangement and number of the support bars SB may be changed in consideration of the degree of sagging of the substrate SU and the rigidity of the support bars SB required to support the substrate SU.

The support frame BF may include a front surface FS adjacent to the substrate SU and a rear surface BS facing the front surface FS. The support bars SB extending in the first direction DR1 may be coupled to the front surface FS of the support frame BF.

The support bar SB may include an extension member LC and a coupling member BC. The extension member LC may be coupled to the support frame BF and extend in the first direction DR1. The coupling member BC may be coupled to the front surface FS of the support frame BF and couple the extension member LC and the support frame BF to each other. The coupling member BC may be disposed between the front surface FS of the support frame BF and one end of the extension member LC.

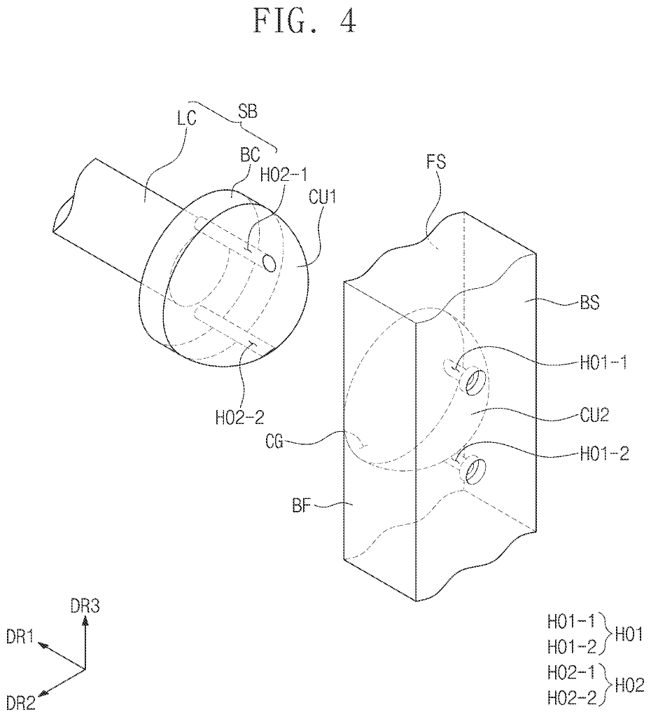

FIG. 4 is a perspective view of a support bar SB and a support frame BF according to an embodiment of the inventive concept.

Referring to FIG. 4, the coupling member BC of the support bar SB may include a first surface CU1 (or a protruding surface) protruding in a direction opposite to the first direction DR1. The first surface CU1 may protrude toward the front surface FS of the support frame BF. The first surface CU1 may have a first curvature and may be a protruding curved surface. The first curvature of the first surface CU1 may be the same as the curvature of a second surface CU2 defining a seating groove CG. The first surface CU1 may be a spherical surface protruding toward the support frame BF.

A second through hole HO2, which overlaps the first surface CU1, extends along the first direction DR1, and passes through the coupling member BC, may be defined in the coupling member BC. The second through hole HO2 may be disposed at a position corresponding to a first through hole HO1 which will be described later. The second through hole HO2 may include a (2-1)-th through hole HO2-1 and a (2-2)-th through hole HO2-2. The (2-1)-th through hole HO2-1 may be disposed at a position corresponding to a (1-1)-th through hole HO1-1. The (2-2)-th through hole HO2-2 may be disposed at a position corresponding to a (1-2)-th through hole HO1-2.

The (2-1)-th through hole HO2-1 and the (2-2)-th through hole HO2-2 may be disposed to be spaced apart from each other along the third direction DR3 with the extension member LC interposed therebetween. The (2-1)-th through hole HO2-1 may be disposed above the extension member LC, and the (2-2)-th through hole HO2-2 may be disposed below the extension member LC.

The seating groove CG in which the first surface CU1 of the coupling member BC is seated may be defined in the support frame BF. The support frame BF may define the seating groove CG and include a second surface CU2 which is a curved surface that faces the first surface CU1 and has the first curvature that is the same as that of the first surface CU1, i.e., has the first curvature of the first surface CU1. The second surface CU2 may be a portion of the front surface FS of the support frame BF. The second surface CU2 may be a curved surface recessed toward the rear surface BS of the support frame BF. The second surface CU2 may be a spherical surface.

The first through hole HO1, which overlaps the second surface CU2, extends along the first direction DR1, and passes through the support frame BF, may be defined in the support frame BF. The position of the first through hole HO1 may correspond to the position of the second through hole HO2. The first through hole HO1 may include the (1-1)-th through hole HO1-1 and the (1-2)-th through hole HO1-2. The (1-1)-th through hole HO1-1 may be disposed at the upper portion of the seating groove CG, and the (1-2)-th through hole HO1-2 may be disposed at the lower portion of the seating groove CG.

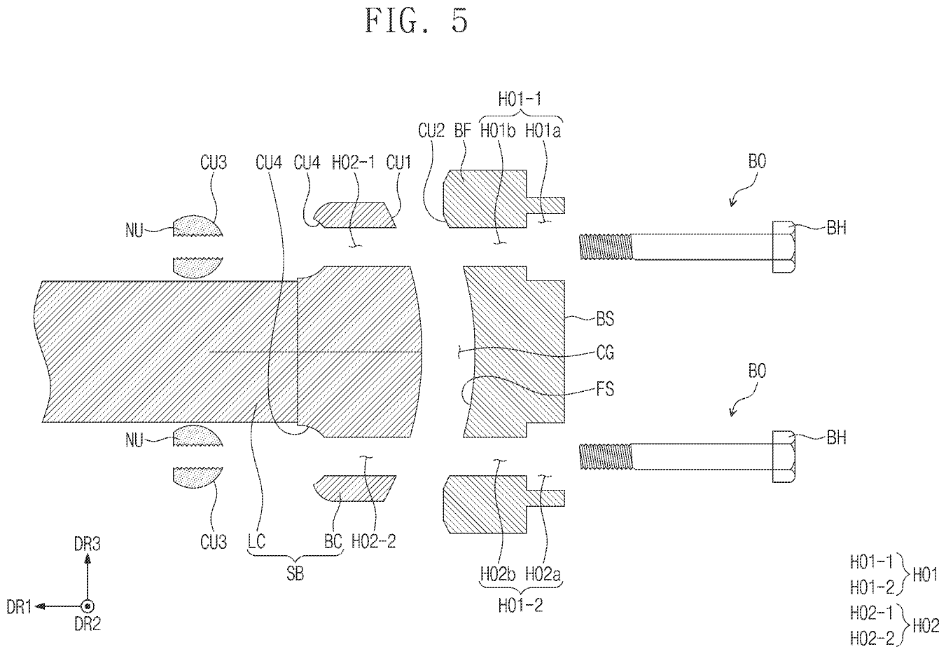

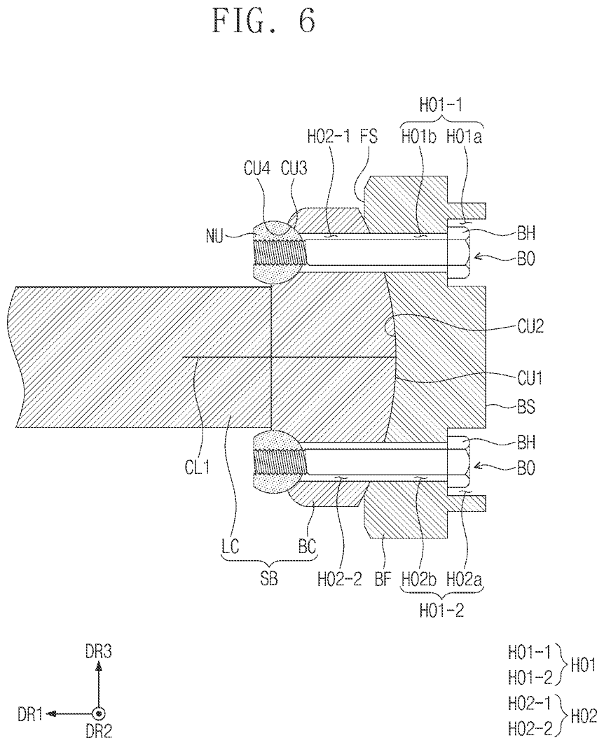

FIG. 5 is a cross-sectional view before coupling the support bar SB and the support frame BF to each other according to an embodiment of the inventive concept. FIG. 6 is a cross-sectional view after coupling the support bar SB and the support frame BF to each other according to an embodiment of the inventive concept. More specifically, FIGS. 5 and 6 illustrate the support bar SB and the support frame BF corresponding to a region AA of FIG. 3.

Referring to FIGS. 5 and 6, the first surface CU1 and the second surface CU2 constituting the seating groove CG may be curved surfaces having the same curvature as each other on a cross section. When the support bar SB and the support frame BF are coupled to each other, the first surface CU1 and the second surface CU2 may be in surface contact with each other. Accordingly, the support bar SB and the support frame BF may be coupled to each other more firmly than when the first surface CU1 and the second surface CU2 are in point contact with each other. For example, when the second surface CU2 is flat and the first surface CU1 is curved, the first surface CU1 and the second surface CU2 are in point contact with each other and it may be difficult for a bolt BO and a nut NU to be firmly fastened to each other. In addition, the combination of the bolt BO and the nut NU may be loosened due to shock and vibration caused by repeated loading and transportation of the substrate SU (see FIG. 1). This may cause sagging of the support bar SB. This limitation may be solved by allowing the first surface CU1 and the second surface CU2 to be in surface contact with each other.

The coupling member BC of the support bar SB and the support frame BF may be coupled to each other by the bolt BO passing through the first through hole HO1 and the second through hole HO2 and the nut NU screwed to the bolt BO. The body portion of the bolt BO disposed above on a cross section may pass through a second portion HO1b of the (1-1)-th through hole HO1-1 and the (2-1)-th through hole HO2-1. The head portion BH of the bolt BO disposed above on a cross section may be seated inside a first portion HO1a of the (1-1)-th through hole HO1-1. The first portion HO1a of the first through hole HO1 may be defined on the rear surface BS of the support frame BF. On a cross section, the head portion BH of the bolt BO may be in surface contact with a portion of the rear surface BS of the support frame BF defining the first portion HO1a. A thread may be defined at the end of the body portion of the bolt BO disposed above on a cross section, and the nut NU may be coupled to the thread. On a cross section, when the support bar SB and the support frame BF are coupled to each other, a first center line CL1 of the support bar SB may be parallel to the first direction DR1.

The body portion of the bolt BO disposed below on a cross section may pass through a second portion HO2b of the (1-2)-th through hole HO1-2 and the (2-2)-th through hole HO2-2. The head portion BH of the bolt BO disposed below on a cross section may be seated inside a first portion HO2a of the (1-2)-th through hole HO1-2. The first portion HO2a of the (1-2)-th through hole HO1-2 may be defined on the rear surface BS of the support frame BF. The head portion BH of the bolt BO disposed below on a cross section may be in surface contact with a portion of the rear surface BS of the support frame BF defining the first portion HO2a. A thread may be defined at the end of the body portion of the bolt BO disposed below on a cross section, and the nut NU may be coupled to the thread.

The nut NU may include a third surface CU3 that is in contact with the coupling member BC and is a curved surface having a second curvature. The coupling member BC may include a fourth surface CU4 that is in contact with the third surface CU3 and is a curved surface having the same second curvature as the third surface CU3. The fourth surface CU4 may have a shape corresponding to the third surface CU3 of the nut NU. The third surface CU3 and the fourth surface CU4 may be a portion of a spherical surface. The fourth surface CU4 may be defined on one surface (hereinafter referred to as the front surface of the coupling member BC) adjacent to the extension member LC among the surfaces of the coupling member BC. As a portion of the front surface of the coupling member BC, the fourth surface CU4 may have a recessed shape corresponding to the third surface CU3. The third surface CU3 and the fourth surface CU4 may be in surface contact with each other so that the bolt BO and nut NU can be stably coupled to each other.

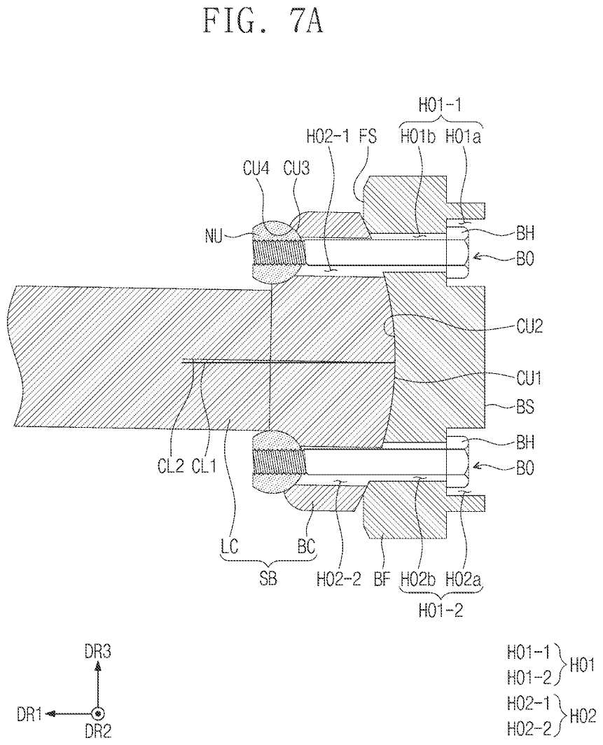

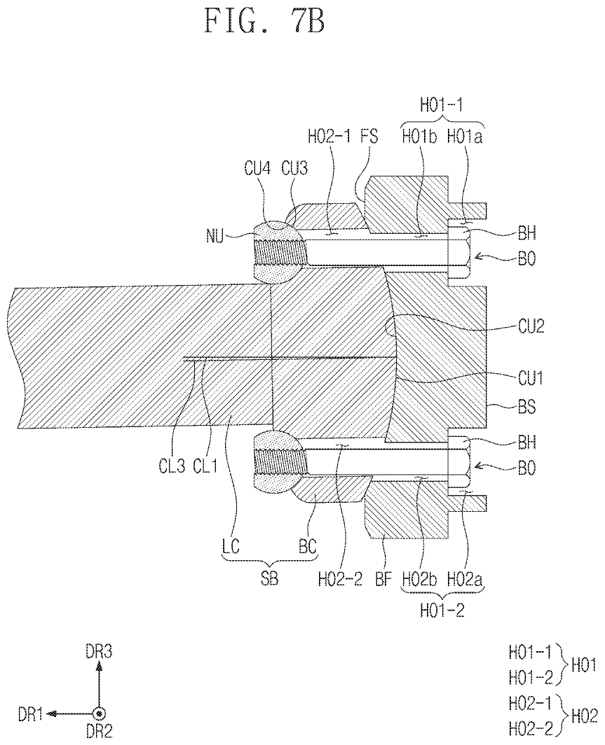

The diameter of the bolt BO may be smaller than the diameter of the first through hole HO1 and the diameter of the second through hole HO2. The bolt BO may be disposed to be spaced apart at a predetermined distance from the inner side surface of the support frame BF defining the first through hole HO1 and the inner side surface of the coupling member BC defining the second through hole HO2. Accordingly, the coupling member BC may partially move while being coupled to the support frame BF. This will be described later with reference to FIGS. 7A and 7B.

FIGS. 7A and 7B are cross-sectional views illustrating a difference in an extension direction of the support bar SB according to an embodiment of the inventive concept. More specifically, FIG. 7A is a cross-sectional view when the extension direction of the support bar SB is more upward than the first direction DR1, and FIG. 7B is a cross-sectional view when the extension direction of the support bar SB is more downward than the first direction DR1.

Referring to FIG. 7A, the support bar SB may be rotated clockwise compared to the support bar SB of FIG. 6. The first surface CU1 may move along the second surface CU2 on the second surface CU2. The first surface CU1 may move clockwise along the second surface CU2 on the second surface CU2. Accordingly, a second center line CL2 of the support bar SB of FIG. 7A may extend upward compared to the first center line CL1 of the support bar SB of FIG. 6. In this case, the bolt BO and the nut NU disposed above may be coupled to each other more firmly than the bolt BO and the nut NU disposed below.

In this way, even when the support bar SB is rotated clockwise, the head portion BH of the bolt BO may be in surface contact with a portion of the rear surface BS of the support frame BF. Since the contact surface between the nut NU and the coupling member BC is a curved surface, the movement of the head portion BH of the bolt BO may be reduced although the support bar SB rotates.

For example, when the contact surface between the nut NU and the coupling member BC is a straight line on a cross section and the support bar SB is rotated clockwise, the head portion BH of the bolt BO may move significantly. Accordingly, the head portion BH of the bolt BO comes into point contact with the support frame BF, and stress applied to the bolt BO may be concentrated in a contact region. Accordingly, an impact may be applied to the bolt BO and the nut NU, and the combination of the bolt BO and the nut NU may be loosened. The above limitation may be solved by making the contact surface between the nut NU and the coupling member BC into a curved surface. In addition, by making the second curvature of the third and fourth surfaces CU3 and CU4 and the first curvature of the first and second surfaces CU1 and CU2 equal to each other, the movement of the head portion BH of the bolt BO may be minimized.

The bolt BO may be disposed to be spaced apart at a predetermined distance from the inner side surface of the support frame BF defining the first through hole HO1 and the inner side surface of the coupling member BC defining the second through hole HO2. That is, since the diameter of each of the first through hole HO1 and the second through hole HO2 is larger than the diameter of the bolt BO, the bolt BO may pass through the first through hole HO1 and the second through hole HO2 even when the support bar SB is rotated. That is, although the extension direction of the (1-1)-th through hole HO1-1 and the extension direction of the (2-1)-th through hole HO2-1 are not parallel to each other, the bolt BO may pass through the (1-1)-th through hole HO1-1 and the (2-1)-th through hole HO2-1. Although the extension direction of the (1-2)-th through hole HO1-2 and the extension direction of the (2-2)-th through hole HO2-2 are not parallel to each other, the bolt BO may pass through the (1-2)-th through hole HO1-2 and the (2-2)-th through hole HO2-2.

Referring to FIG. 7B, the support bar SB may be rotated counterclockwise compared to the support bar SB of FIG. 6. The first surface CU1 may move counterclockwise along the second surface CU2 on the second surface CU2. Accordingly, a third center line CL3 of the support bar SB of FIG. 7B may extend downward compared to the first center line CL1 of the support bar SB of FIG. 6. In this case, the bolt BO and the nut NU disposed below may be coupled to each other more strongly than the bolt BO and the nut NU disposed above.

In this way, even when the support bar SB is rotated counterclockwise, the head portion BH of the bolt BO may come into surface contact with a portion of the rear surface BS of the support frame BF. Since the contact surface between the nut NU and the coupling member BC is a curved surface, the movement of the head portion BH of the bolt BO may be reduced although the support bar SB rotates. The second curvature of the third and fourth surfaces CU3 and CU4 may be the same as the first curvature of the first and second surfaces CU1 and CU2.

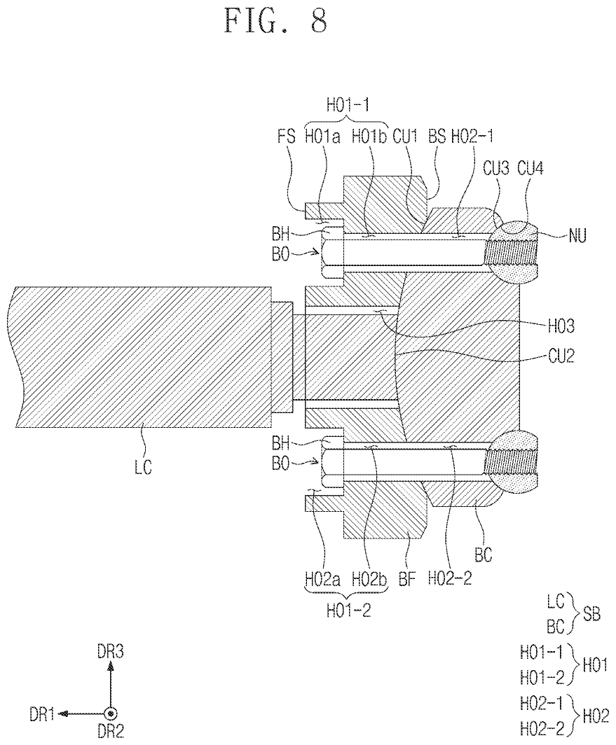

FIG. 8 is a cross-sectional view after coupling a support bar SB and a support frame BF to each other according to an embodiment of the inventive concept. The support bar SB and support frame BF illustrated in FIG. 8 are the same as the support bar SB and the support frame BF illustrated in FIG. 6 except for a third through hole HO3, the positions of the first surface CU1 and the second surface CU2, the position of the coupling member BC, and the positions of the (1-1)-th through hole HO1-1 and the (1-2)-th through hole HO1-2. Accordingly, the descriptions of the components which are the same as those of FIG. 6 will be omitted.

Referring to FIG. 8, the third through hole HO3 extending in the first direction DR1 may be defined in the center of the support frame BF. The extension member LC may pass through the third through hole HO3. The coupling member BC may be coupled to one end of the extension member LC that has passed through the third through hole HO3. The extension member LC of the support bar SB may be disposed on the front surface FS, and the coupling member BC of the support bar SB may be disposed on the rear surface BS.

The coupling member BC may include the first surface CU1 (a protruding surface) protruding in the first direction DR1. The first surface CU1 may protrude toward the rear surface BS of the support frame BF. Except the characteristics of the first surface CU1 described above, the characteristics of the first surface CU1 are the same as those of the first surface CU1 described in FIG. 6.

The support frame BF may define a seating groove CG and include the second surface CU2 which is a curved surface facing the first surface CU1 and having the same first curvature as the first surface CU1. The second surface CU2 may be a portion of the rear surface BS of the support frame BF. The second surface CU2 may be a curved surface recessed toward the front surface FS of the support frame BF. The second surface CU2 may be a spherical surface. Except the characteristics of the second surface CU2 described above, the characteristics of the second surface CU2 are the same as those of the second surface CU2 described in FIG. 6.

The first portion HO1a of the (1-1)-th through hole HO1-1 may be defined on the front surface FS of the support frame BF. The first portion HO2a of the (1-2)-th through hole HO1-2 may be disposed on the front surface FS of the support frame BF. The head portion BH of the bolt BO accommodated inside the first portion HO1a or HO2a may be disposed adjacent to the front surface FS of the support frame BF, and the nut NU may be disposed adjacent to the rear surface BS of the support frame BF.

Since the coupling member BC is disposed on the rear surface BS of the support frame BF as illustrated in FIG. 8, the width of the slot SLU (see FIG. 3) in the first direction DR1 in FIG. 3 may be widened.

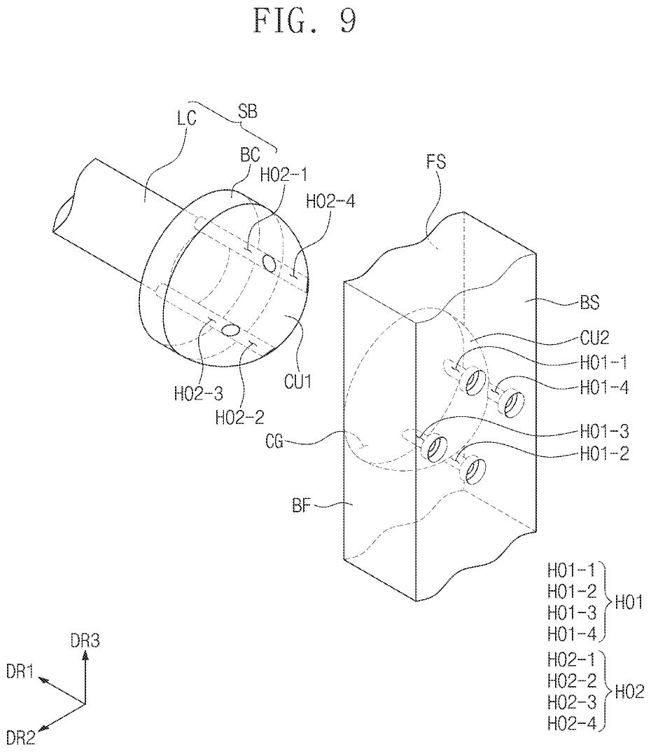

FIG. 9 is a perspective view of a support bar SB and a support frame BF according to an embodiment of the inventive concept.

Since the support bar SB and support frame BF of FIG. 9 are the same as the support bar SB and the support frame BF described in reference to FIG. 4 except for the number of the first through holes HO1 and the second through holes HO2, the descriptions of the same components will be omitted.

Referring to FIG. 9, the first through hole HO1 may include a (1-1)-th through hole HO1-1, a (1-2)-th through hole HO1-2, a (1-3)-th through hole HO1-3, and a (1-4)-th through hole HO1-4. The (1-1)-th through hole HO1-1 and the (1-2)-th through hole HO1-2 may be arranged along the third direction DR3, and the (1-3)-th through hole HO1-3 and the (1-4)-th through holes HO1-4 may be arranged along the second direction DR2. The (1-1)-th to (1-4)-th through holes HO1-1, HO1-2, HO1-3, and HO1-4 may be disposed in positions respectively corresponding to (2-1)-th to (2-4)-th through holes HO2-1, HO2-2, HO2-3, and HO2-4.

The second through hole HO2 may include the (2-1)-th through hole HO2-1, the (2-2)-th through hole HO2-2, the (2-3)-th through hole HO2-3, and the (2-4)-th through hole HO2-4. The (2-1)-th through hole HO2-1 and the (2-2)-th through hole HO2-2 may be arranged along the third direction DR3 with the extension member LC interposed therebetween. The (2-3)-th through hole HO2-3 and the (2-4)-th through hole HO2-4 may be arranged along the second direction DR2 with the extension member LC interposed therebetween.

By adjusting the fastening degree of the bolt passing through the (2-1)-th through hole HO2-1 and the (2-2)-th through hole HO2-2 and the nut coupled thereto, the extension direction of the extension member LC may be adjusted to an upward direction or a downward direction. By adjusting the fastening degree of the bolt passing through the (2-3)-th through hole HO2-3 and the (2-4)-th through hole HO2-4 and the nut coupled thereto, the extension direction of the extension member LC may be adjusted to a leftward direction or a rightward direction.

Since the substrate loading apparatus according to an embodiment of the inventive concept is provided with the support frame having a seating groove which is defined therein and has a curved surface corresponding to the curved surface of the support bar, it is possible for the support bar and the support frame to be firmly coupled to each other.

In addition, the extension direction of the support bar may be adjusted by adjusting the combination of a bolt and a nut.

Although the above has been described with reference to embodiments of the inventive concept, those skilled in the art or those of ordinary skill in the art will understand that various modifications and changes can be made to the inventive concept within the scope that does not depart from the spirit and technical field of the inventive concept described in the claims to be described later. Accordingly, the technical scope of the inventive concept should not be limited to the content described in the detailed description of the specification, but should be determined by the claims described hereinafter.

What is claimed is:

1. A substrate loading apparatus comprising:
a first frame and a second frame facing each other;
a support frame disposed between the first frame and the second frame, extending along a first direction, and comprising a front surface adjacent to a substrate and a rear surface facing the front surface; and
a support bar coupled to the support frame, extending in a second direction crossing the first direction, and supporting the substrate,
wherein the support bar comprises an extension member extending in the second direction and a coupling member coupling the extension member and the support frame to each other,
wherein the coupling member comprises a first surface, which protrudes toward the support frame and is a curved surface having a first curvature,
wherein the support frame comprises a second surface, which faces the first surface and is a curved surface having the first curvature of the first surface, and
wherein the first surface and the second surface are in surface contact with each other.

2. The substrate loading apparatus of claim 1, wherein the first surface and the second surface are spherical surfaces.

3. The substrate loading apparatus of claim 1, wherein:
the support frame has a first through hole which is defined therein, overlaps the second surface, extends along the second direction, and passes through the support frame; and
the coupling member has a second through hole which is defined therein, overlaps the first surface, extends along the second direction, and passes through the coupling member.

4. The substrate loading apparatus of claim 3, further comprising:
a bolt passing through the first and second through holes; and
a nut screwed to the bolt,
wherein the coupling member and the support frame are coupled to each other by the bolt and the nut.

5. The substrate loading apparatus of claim 4, wherein:
the nut comprises a third surface which is in contact with the coupling member and is a curved surface having a second curvature; and
the coupling member comprises a fourth surface which is in surface contact with the third surface and is a curved surface having the second curvature of the third surface.

6. The substrate loading apparatus of claim 4, wherein a head portion of the bolt is in surface contact with the support frame.

7. The substrate loading apparatus of claim 5, wherein the first curvature and the second curvature are the same as each other.

8. The substrate loading apparatus of claim 5, wherein the third surface and the fourth surface are spherical surfaces.

9. The substrate loading apparatus of claim 4, wherein the bolt is spaced apart by a predetermined distance from an inner side surface of the support frame defining the first through hole and an inner side surface of the coupling member defining the second through hole.

10. The substrate loading apparatus of claim 3, wherein:
the second through hole is provided in plurality, and the plurality of second through holes comprise (2-1)-th and (2-2)-th through holes disposed along the first direction with the extension member interposed therebetween; and
the first through hole is provided in plurality, and the plurality of first through holes comprise (1-1)-th and (1-2)-th through holes disposed at positions respectively corresponding to the (2-1)-th and (2-2)-th through holes.

11. The substrate loading apparatus of claim 3, wherein:
the second through hole is provided in plurality, and the plurality of second through holes comprise (2-3)-th and (2-4)-th through holes disposed along a third direction crossing the first direction and the second direction with the extension member interposed therebetween; and
the first through hole is provided in plurality, and the plurality of first through holes comprise (1-3)-th and (1-4)-th through holes disposed at positions respectively corresponding to the (2-3)-th and (2-4)-th through holes.

12. The substrate loading apparatus of claim 1, wherein the second surface is a portion of the front surface.

13. The substrate loading apparatus of claim 1, wherein:
a third through hole through which the extension member passes is defined in the support frame; and
the second surface is a portion of the rear surface.

14. The substrate loading apparatus of claim 1, wherein the first surface is able to move along the second surface.

15. A substrate loading apparatus comprising:
a support frame extending along a first direction and comprising a front surface adjacent to a substrate and a rear surface facing the front surface; and
a support bar coupled to the support frame, extending in a second direction crossing the first direction, and supporting the substrate,
wherein the support bar comprises an extension member extending in the second direction and a coupling member coupling the extension member and the support frame to each other,
wherein the coupling member comprises a protruding surface that is a spherical surface protruding toward the support frame,
wherein a seating groove in which the protruding surface is seated is defined in the support frame, and
wherein the protruding surface and one surface of the support frame defining the seating groove are in surface contact with each other.

16. The substrate loading apparatus of claim 15, wherein:
a first through hole, which overlaps the seating groove, extends along the second direction, and passes through the support frame, is defined in the support frame; and
a second through hole, which overlaps the protruding surface, extends along the second direction, and passes through the coupling member, is defined in the coupling member.

17. The substrate loading apparatus of claim 16, further comprising:
a bolt which passes through the first and second through holes; and
a nut screwed to the bolt,
wherein:
one surface of the nut is a first curved surface; and
a contact surface of the coupling member in contact with the one surface is a second curved surface corresponding to the first curved surface.

18. The substrate loading apparatus of claim 17, wherein a head portion of the bolt is in surface contact with the support frame.

19. The substrate loading apparatus of claim 16, wherein:
the first through hole is provided in plurality, and the plurality of first through holes comprise (1-3)-th and (1-4)-th through holes disposed along a third direction crossing the first direction and the second direction with the extension member interposed therebetween; and
the second through hole is provided in plurality, and the plurality of second through holes comprise (2-3)-th and (2-4)-th through holes disposed at positions respectively corresponding to the (1-3)-th and (1-4)-th through holes.

20. The substrate loading apparatus of claim 15, wherein:
a third through hole through which the extension member passes is defined in the support frame; and
the seating groove is defined on the rear surface.
